(19) United States
(12) Patent Application Publication
(10) Pub. No.: US 2012/0175755 A1
(43) Pub. Date: Jul. 12, 2012

(54) SEMICONDUCTOR DEVICE INCLUDING A HEAT SPREADER

(75) Inventor: Reinhold Bayerer, Warstein (DE)

(73) Assignee: INFINEON TECHNOLOGIES AG, Neubiberg (DE)

(21) Appl. No.: 13/005,279

(22) Filed: Jan. 12, 2011

(51) Int. Cl. H01L 23/34; H01L 21/50

(52) U.S. Cl. 257/675; 438/122; 257/E23.08; 257/E21.499

(57) ABSTRACT

A semiconductor device includes a semiconductor chip including back side metal, a substrate, and an electrically conductive heat spreader directly contacting the back side metal. The semiconductor chip includes a sintered joint directly contacting the heat spreader and electrically coupling the heat spreader to the substrate.

### BACKGROUND

Power electronic modules are semiconductor packages that are used in power electronic circuits. Power electronic modules are typically used in vehicular and industrial applications, such as in inverters and rectifiers. The semiconductor components included within the power electronic modules are typically insulated gate bipolar transistor (IGBT) semiconductor chips or metal-oxide-semiconductor field effect transistor (MOSFET) semiconductor chips. The IGBT and MOSFET semiconductor chips have varying voltage and current ratings. Some power electronic modules also include additional semiconductor diodes (i.e., free-wheeling diodes) in the semiconductor package for overvoltage protection.

In general, two different power electronic module designs are used. One design is for higher power applications and the other design is for lower power applications. For higher power applications, a power electronic module typically includes several semiconductor chips integrated on a single substrate. The substrate typically includes an insulating ceramic substrate, such as Al₂O₃, AlN, Si₃N₄, or other suitable material, to insulate the power electronic module. At least the top side of the ceramic substrate is metallized with either pure or plated Cu, Al, or other suitable material to provide electrical and mechanical contacts for the semiconductor chips. The metal layer is typically bonded to the ceramic substrate using a direct copper bonding (DCB) process, a direct aluminum bonding process (DAB) process, or an active metal brazing (AMB) process.

Typically, soft soldering with Sn—Pb, Sn—Ag, Sn—Ag—Cu, or another suitable solder alloy is used for joining a semiconductor chip to a metallized ceramic substrate. Typically, several substrates are combined onto a metal baseplate. In this case, the backside of the ceramic substrate is also metallized with either pure or plated Cu, Al, or other suitable material for joining the substrates to the metal baseplate. To join the substrates to the metal baseplate, soft soldering with Sn—Pb, Sn—Ag, Sn—Ag—Cu, or another suitable solder alloy is typically used.

For lower power applications, instead of ceramic substrates, leadframe substrates (e.g., pure Cu substrates) are typically used. Depending upon the application, the leadframe substrates are typically plated with Ni, Ag, Au, and/or Pd. Typically, soft soldering with Sn—Pb, Sn—Ag, Sn—Ag—Cu, or another suitable solder alloy is used for joining a semiconductor chip to a leadframe substrate.

For high temperature applications, the low melting point of the solder joints (Tₘ=180° C.−220° C.) becomes a critical parameter for power electronic modules. During operation of power electronic modules, the areas underneath the semiconductor chips are exposed to high temperatures. In these areas, the ambient air temperature is superposed by the heat that is dissipated inside the semiconductor chip. This leads to a thermal cycling during operation of the power electronic modules. Typically, with respect to thermal cycling reliability, a reliable function of a solder joint cannot be guaranteed above 150° C. Above 150° C., cracks may form inside the solder region after a few thermal cycles. The cracks can easily spread over the entire solder region and lead to the failure of the power electronic module.

With the increasing desire to use power electronics in harsh environments (e.g., automotive applications) and the ongoing integration of semiconductor chips, the externally and internally dissipated heat continues to increase. Therefore, there is a growing demand for high temperature power electronic modules capable of operating with internal and external temperatures up to and exceeding 200° C. In addition, the current density of power electronics continues to increase, which leads to an increase in the density of power losses. Therefore, the thermal interface between the semiconductor chip and the substrate through which the losses have to be dissipated becomes increasingly important.

For these and other reasons, there is a need for the present invention.

### SUMMARY

One embodiment provides a semiconductor device. The semiconductor device includes a semiconductor chip including back side metal, a substrate, and an electrically conductive heat spreader directly contacting the back side metal. The semiconductor chip includes a sintered joint directly contacting the heat spreader and electrically coupling the heat spreader to the substrate.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a cross-sectional view of one embodiment of a semiconductor device.

FIG. 2 illustrates a cross-sectional view of another embodiment of a semiconductor device.

FIG. 3 illustrates a cross-sectional view of one embodiment of a portion of a semiconductor device including an electrical and thermal interface between a semiconductor chip and a substrate.

FIG. 4 illustrates a cross-sectional view of one embodiment of a portion of a semiconductor device including electrical and thermal interfaces between a semiconductor chip and two substrates.

FIG. 5A illustrates a cross-sectional view of one embodiment of a heat spreader.

FIG. 5B illustrates a cross-sectional view of another embodiment of a heat spreader.

FIG. 5C illustrates a cross-sectional view of another embodiment of a heat spreader.

### DETAILED DESCRIPTION

In the following Detailed Description, reference is made to the accompanying drawings, which form a part hereof, and in which is shown by way of illustration specific embodiments in which the disclosure may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As used herein, the term “electrically coupled” is not meant to mean that the elements must be directly coupled together and intervening elements may be provided between the “electrically coupled” elements.

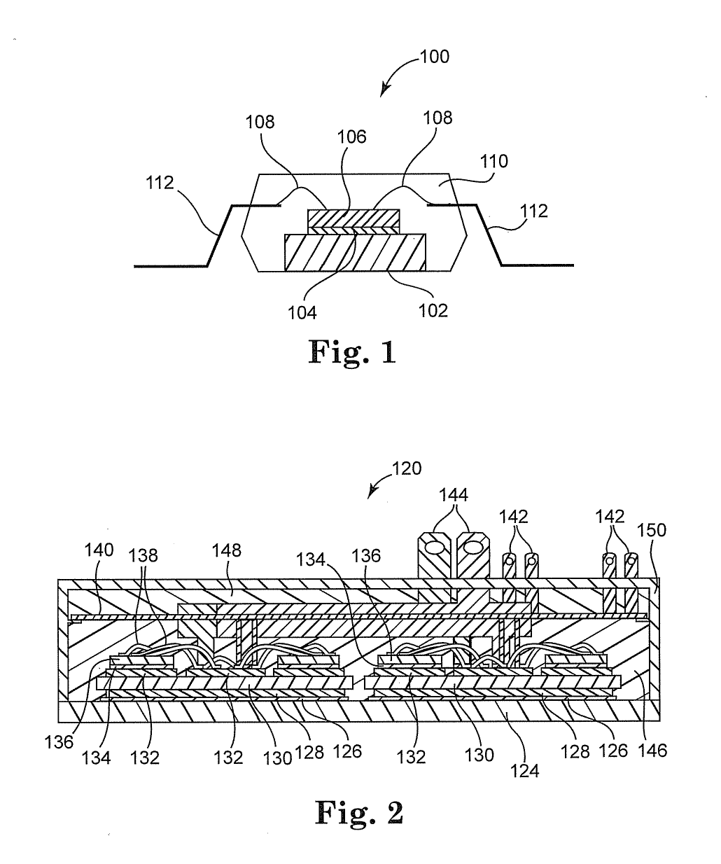

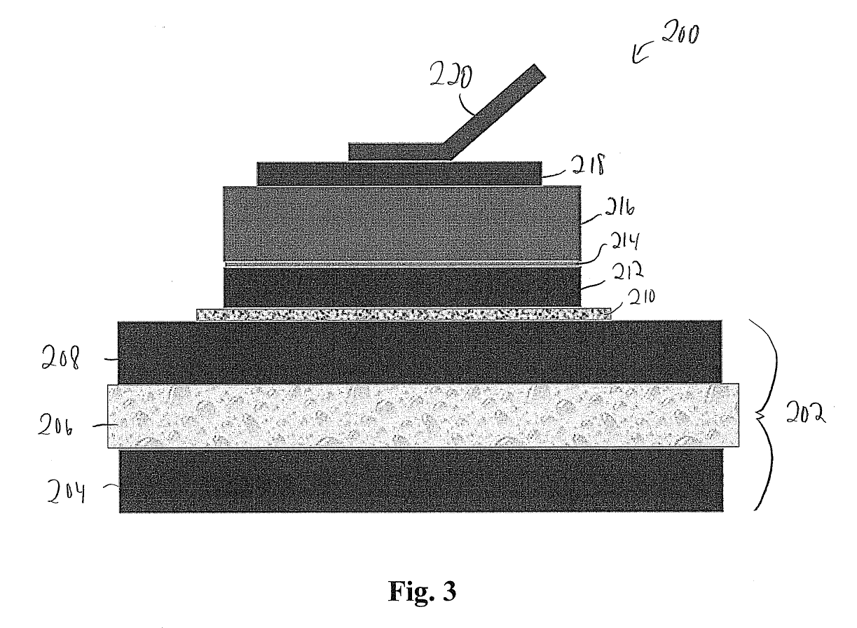

FIG. 1 illustrates a cross-sectional view of one embodiment of a semiconductor device 100. In one embodiment, semiconductor device 100 is a high temperature (i.e., up to and exceeding 200° C.) low power electronic module. Power electronic module 100 includes a leadframe substrate 102, an electrical and thermal interface 104, a semiconductor chip or die 106, bond wires 108, leads 112, and a housing 110. Leadframe substrate 102 includes Cu, Al, or another suitable material. In one embodiment, leadframe substrate 102 is plated with Ni, Ag, Au, and/or Pd. In one embodiment, electrical and thermal interface 104 includes a heat spreader and a sintered joint, which will be described in more detail below with reference to FIGS. 3-5C. Electrical and thermal interface 104 joins leadframe substrate 102 to semiconductor chip 106.

The sintered joint may include voids or imperfections due to the fabrication process. The voids or imperfections of the sintered joint may range in size between a few micrometers and 20 μm. These voids or imperfections of the sintered joint reduce the effectiveness of the sintered joint in dissipating heat from the semiconductor chip 106. To reduce the effect of the voids or imperfections of the sintered joint in dissipating heat from the semiconductor chip 106, a heat spreader is formed between the semiconductor chip 106 and the sintered joint. The heat spreader provides a buffer between the semiconductor chip 106 and the sintered joint to dissipate the heat from the semiconductor chip 106 around the voids or imperfections of the sintered joint. By spreading the dissipated heat from the semiconductor chip 106 around the voids or imperfections of the sintered joint, the thermal interface between the semiconductor chip 106 and leadframe substrate 102 is substantially improved compared to a thermal interface that includes only the sintered joint and not a heat spreader.

Semiconductor chip 106 is electrically coupled to leads 112 through bond wires 108. Bond wires 108 include Al, Cu, Al—Mg, Au, or another suitable material. In one embodiment, bond wires 108 are bonded to semiconductor chip 106 and leads 112 using ultrasonic wire bonding. In one embodiment, leadframe substrate 102 has a thickness within the range of 125 μm to 200 μm. Leadframe substrate 102 is joined to semiconductor chip 106 via electrical and thermal interface 104 using a low temperature joining (LTJ) process. Housing 110 includes a mould material or another suitable material. Housing 110 surrounds leadframe substrate 102, electrical and thermal interface 104, semiconductor chip 106, bond wires 108, and portions of leads 112.

FIG. 2 illustrates a cross-sectional view of another embodiment of a semiconductor device 120. In one embodiment, semiconductor device 120 is a high temperature (i.e., up to and exceeding 200° C.) high power electronic module. Power electronic module 120 includes a metal baseplate 124, sintered joints 126, metalized ceramic substrates 130 including metal surfaces or layers 128 and 132, electrical and thermal interfaces 134, semiconductor chips 136, bond wires 138, circuit board 140, control contacts 142, power contacts 144, potting 146 and 148, and housing 150.

Ceramic substrates 130 include Al₂O₃, AlN, Si₃N₄, or other suitable material. In one embodiment, ceramic substrates 130 each have a thickness within a range of 0.2 mm to 2.0 mm. Metal layers 128 and 132 include Cu, Al, or another suitable material. In one embodiment, metal layers 128 and/or 132 are plated with Ni, Ag, Au, and/or Pd. In one embodiment, metal layers 128 and 132 each have a thickness within a range of 0.1 mm to 0.6 mm. Sintered joints 126 join metal layers 128 to metal baseplate 124. Electrical and thermal interfaces 134 join metal layers 132 to semiconductor chips 136. Each electrical and thermal interface 134 includes a heat spreader and a sintered joint similar to electrical and thermal interface 104 previously described and illustrated with reference to FIG. 1.

Semiconductor chips 136 are electrically coupled to metal layers 132 through bond wires 138. Bond wires 138 include Al, Cu, Al—Mg, Au, or another suitable material. In one embodiment, bond wires 138 are bonded to semiconductor chips 136 and metal layers 132 using ultrasonic wire bonding. Metal layers 132 are electrically coupled to circuit board 140 and power contacts 144. Circuit board 140 is electrically coupled to control contacts 142.

Housing 150 encloses sintered joints 126, metallized ceramic substrates 130 including metal layers 128 and 132, electrical and thermal interfaces 134, semiconductor chips 136, bond wires 138, circuit board 140, portions of control contacts 142, and portions of power contacts 144. Housing 150 includes technical plastics or another suitable material. Housing 150 is joined to metal baseplate 124. In one embodiment, a single metallized ceramic substrate 130 is used such that metal baseplate 124 is excluded and housing 150 is joined directly to the single metallized ceramic substrate 130.

Potting material 146 fills areas below circuit board 140 within housing 150 around sintered joints 126, metallized ceramic substrates 130 including metal layers 128 and 132, electrical and thermal interfaces 134, semiconductor chips 136, and bond wires 138. Potting material 148 fills the area above circuit board 150 within housing 150 around portions of control contacts 142 and portions of power contacts 144. Potting material 146 and 148 includes silicone gel or another suitable material. Potting material 146 and 148 prevents damage to power electronic module 120 by dielectrical breakdown.

FIG. 3 illustrates a cross-sectional view of one embodiment of a portion 200 of a semiconductor device including an electrical and thermal interface between a semiconductor chip 216 and a substrate 202. In one embodiment, portion 200 can be used in module 100 or module 120 previously described and illustrated with reference to FIGS. 1 and 2, respectively. Portion 200 includes a metallized ceramic substrate 202, a sintered joint 210, a heat spreader 212, semiconductor chip back side metal 214, semiconductor chip 216, semiconductor chip front side metal 218, and bond wire 220.

Metallized ceramic substrate 202 includes a ceramic substrate 206, a first metal layer 204 directly contacting a first side of ceramic substrate 206, and a second metal layer 208 directly contacting a second side of ceramic substrate 206 opposite the first side. Ceramic substrate 206 includes Al₂O₃, AlN, Si₃N₄, or other suitable material. Metal layers 204 and 208 include Cu, Al, or another suitable material. In one embodiment, metal layers 204 and/or 208 are plated with Ni, Ag, Au, and/or Pd. In one embodiment, metal layers 204 and 208 are bonded to ceramic substrate 206 using a direct copper bonding (DCB) process, a direct aluminum bonding process (DAB) process, or an active metal brazing (AMB) process. In another embodiment, metallized ceramic substrate 202 is replaced with a leadframe substrate, such as leadframe substrate 102 previously described and illustrated with reference to FIG. 1.

Sintered joint 210 electrically couples metal layer 208 of metallized ceramic substrate 202 to heat spreader 212. In another embodiment, sintered joint 210 electrically couples a leadframe substrate to heat spreader 212. Sintered joint 210 is a sintered metal layer including sintered nanoparticles, such as Ag nanoparticles, Au nanoparticles, Cu nanoparticles, or other suitable nanoparticles. Sintered joint 210 may include voids or imperfections due to the fabrication process.

Heat spreader 212 directly contacts sintered joint 210 and semiconductor chip back side metal 214 and provides a buffer between semiconductor chip 216 and sintered joint 210 for dissipating heat from semiconductor chip 216 around voids or imperfections of sintered joint 210. In one embodiment, heat spreader 212 includes a solid planar material layer having the same length and width as semiconductor chip 216 such that heat spreader 212 covers the entire back side of semiconductor chip 216. In one embodiment, heat spreader 212 includes a layer of material having high thermal conductivity, such as Cu, Ag, carbon nanotubes, or other suitable material. Carbon nanotubes having a thermal conductivity of up to 2000 W/mK may be mixed into metal layers to provide heat spreader 212.

In one embodiment, a layer of material for heat spreader 212 is deposited or grown on semiconductor chip back side metal 214 during wafer processing. By depositing or growing the material layer during wafer processing, a layer having a low defect density can be achieved. Heat spreader 212 has a thickness of at least 4 μm between semiconductor chip back side metal 214 and sintered joint 210. In other embodiments, heat spreader 212 has a thickness between 4 μm and 100 μm, such as 5 μm, 8 μm, 10 μm, 20 μm, 50 μm, or 100 μm. In addition, in one embodiment heat spreader 212 has a thermal conductively of at least 300 W/mK.

Semiconductor chip back side metal 214 electrically and thermally couples the back side of semiconductor chip 216 to heat spreader 212. Semiconductor chip back side metal 214 includes any suitable metal layer or stack of metal layers. In one embodiment, semiconductor chip back side metal 214 includes a Cr/Ni/Ag, Al/X/Y/Ni/Ag, or Al/X/Y/Ni/Au layer stack, where “X” and “Y” are any suitable metals. In one embodiment, the thickness of semiconductor chip back side metal 214 is 1 μm or less. Due to the relatively small thickness of 1 μm or less of semiconductor chip back side metal 214, the semiconductor chip back side metal by itself does not significantly contribute to heat spreading.

Semiconductor chip 216 includes a power semiconductor component, such as an insulated gate bipolar transistor (IGBT), a metal-oxide-semiconductor field effect transistor (MOSFET), and/or diodes (i.e., free-wheeling diodes). Without heat spreader 212, the Si of semiconductor chip 216, which has a thermal conductivity of at least three times less than heat spreader 212, would have to spread the heat around the voids or imperfections of sintered joint 210. Semiconductor chip front side metal 218 electrically couples the front side of semiconductor chip 216 to bond wire 220. Semiconductor chip front side metal 218 includes Cu, Al, or another suitable material. In one embodiment, semiconductor chip front side metal 218 is plated with Ni, Ag, Au, and/or Pd. Bond wire 220 includes Al, Cu, Al—Mg, Au, or another suitable material.

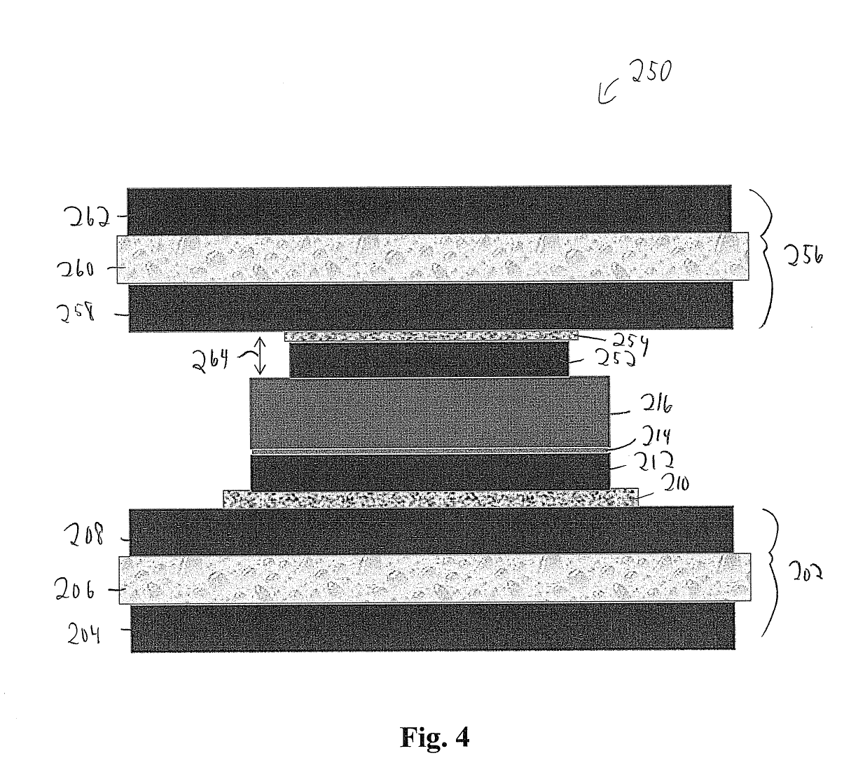

FIG. 4 illustrates a cross-sectional view of one embodiment of a portion 250 of a semiconductor device including electrical and thermal interfaces between a semiconductor chip 216 and substrates 202 and 256. In one embodiment, portion 250 can be used in module 120 previously described and illustrated with reference to FIG. 2. Portion 250 includes a first metallized ceramic substrate 202, a first sintered joint 210, a first heat spreader 212, semiconductor chip back side metal 214, semiconductor chip 216, a second heat spreader 252, a second sintered joint 254, and a second metallized ceramic substrate 256.

First metallized ceramic substrate 202, first sintered joint 210, first heat spreader 212, semiconductor chip back side metal 214, and semiconductor chip 216 are the same as previously described and illustrated with reference to FIG. 3. Second metallized ceramic substrate 256 is similar to metallized ceramic substrate 202 and includes a ceramic substrate 260, a first metal layer 258 directly contacting a first side of ceramic substrate 260, and a second metal layer 262 directly contacting a second side of ceramic substrate 260 opposite the first side.

Second sintered joint 254 electrically couples metal layer 258 of second metallized ceramic substrate 256 to second heat spreader 252. Sintered joint 254 is similar to sintered joint 210 and is a sintered metal layer including sintered nanoparticles, such as Ag nanoparticles, Au nanoparticles, Cu nanoparticles, or other suitable nanoparticles. Sintered joint 254 may include voids or imperfections due to the fabrication process.

Second heat spreader 252 directly contacts sintered joint 254 and semiconductor chip 216 and provides a buffer between semiconductor chip 216 and sintered joint 254 for dissipating heat from semiconductor chip 216 around voids or imperfections of sintered joint 254. In one embodiment, second heat spreader 252 includes a solid planar material layer having a slightly smaller length and/or width than semiconductor chip 216 such that second heat spreader 252 covers the majority of the front side of semiconductor chip 216. In one embodiment, second heat spreader 252 includes a layer of material having high thermal conductivity, such as Cu, Ag, carbon nanotubes, or other suitable material. Carbon nanotubes having a thermal conductivity of up to 2000 W/mK may be mixed into metal layers to provide second heat spreader 252.

In one embodiment, a layer of material for second heat spreader 252 is deposited or grown on the front side of semiconductor chip 216 during wafer processing. By depositing or growing the material layer during wafer processing, a layer having a low defect density can be achieved. Second heat spreader 252 has a thickness of at least 4 μm between the front side of semiconductor chip 216 and sintered joint 254. In other embodiments, second heat spreader 252 has a thickness between 4 μm and 100 μm, such as 5 μm, 8 μm, 10 μm, 20 μm, 50 μm, or 100 μm. In one embodiment, the thickness of second heat spreader 252 is selected such that a distance 264 between semiconductor chip 216 and second metallized ceramic substrate 256 is suitable for isolating an edge termination of semiconductor chip 216 from second metallized ceramic substrate 256. In addition, in one embodiment second heat spreader 212 has a thermal conductively of at least 300 W/mK.

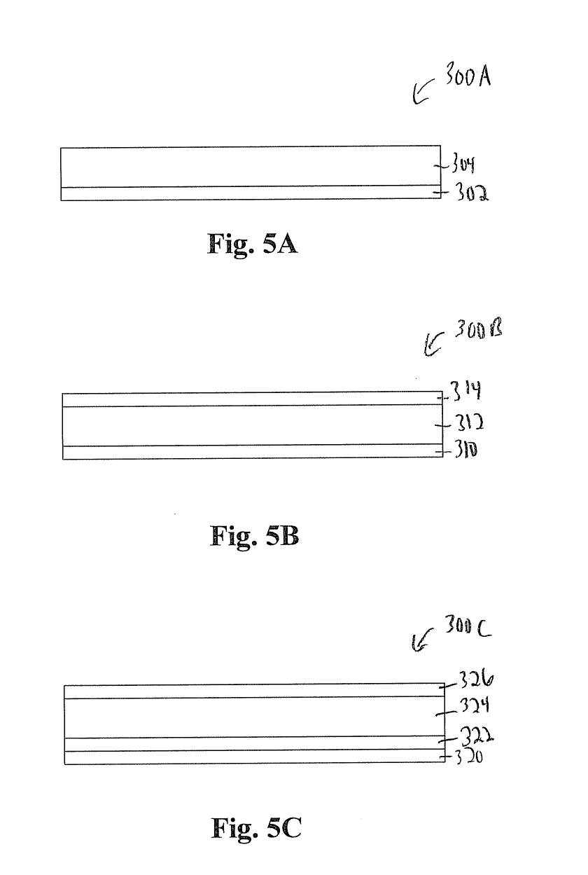

FIG. 5A illustrates a cross-sectional view of one embodiment of a heat spreader 300A. In one embodiment, heat spreader 300A is used in place of heat spreader 212 and/or 252 previously described and illustrated with reference to FIGS. 3 and 4. Heat spreader 300A includes a stack of a first solid planar metal layer 302 and a second solid planar metal layer 304. In this embodiment, first metal layer 302 is a Ag layer and second metal layer 304 is a Cu layer to provide a Cu/Ag layer stack. The thickness of second metal layer 304 is greater than the thickness of first metal layer 302. In a semiconductor device, first metal layer 302 directly contacts the sintered joint while second metal layer 304 directly contacts the semiconductor chip or the back side metal of the semiconductor chip.

FIG. 5B illustrates a cross-sectional view of another embodiment of a heat spreader 300B. In one embodiment, heat spreader 300B is used in place of heat spreader 212 and/or 252 previously described and illustrated with reference to FIGS. 3 and 4. Heat spreader 300B includes a stack of a first solid planar metal layer 310, a second solid planar metal layer 312, and a third solid planar metal layer 314. In this embodiment, first metal layer 310 is a Ag layer, second metal layer 312 is a Cu layer, and third metal layer 314 is a Ni layer to provide a Ni/Cu/Ag layer stack.

The thickness of second metal layer 312 is greater than the thickness of first metal layer 310 and the thickness of third metal layer 314. In one embodiment, the thickness of second metal layer 312 is greater than the thicknesses of first metal layer 310 and third metal layer 314 combined. In a semiconductor device, first metal layer 310 directly contacts the sintered joint while third metal layer 314 directly contacts the semiconductor chip or the back side metal of the semiconductor chip.

FIG. 5C illustrates a cross-sectional view of another embodiment of a heat spreader 300C. In one embodiment, heat spreader 300C is used in place of heat spreader 212 and/or 252 previously described and illustrated with reference to FIGS. 3 and 4. Heat spreader 300C includes a stack of a first solid planar metal layer 320, a second solid planar metal layer 322, a third solid planar metal layer 324, and a fourth solid planar metal layer 326. In this embodiment, first metal layer 320 is a Au layer, second metal layer 322 is a Ni layer, third metal layer 324 is a Cu layer, and fourth metal layer 326 is a Ni layer to provide a Ni/Cu/Ni/Au layer stack.

The thickness of third metal layer 324 is greater than the thickness of first metal layer 320, the thickness of second metal layer 322, and the thickness of fourth metal layer 326. In one embodiment, the thickness of third metal layer 324 is greater than the thicknesses of first metal layer 320, second metal layer 322, and fourth metal layer 326 combined. In a semiconductor device, first metal layer 320 directly contacts the sintered joint while fourth metal layer 326 directly contacts the semiconductor chip or the back side metal of the semiconductor chip.

Embodiments provide a semiconductor device in which a relatively thick conductor layer is applied during wafer processing as a buffer between a semiconductor chip and a sintered joint. The conductor layer spreads heat dissipated by the semiconductor chip around any voids or imperfections of the sintered joint, thereby improving the thermal interface between the semiconductor chip and the substrate(s) to which the semiconductor chip is attached.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A semiconductor device comprising:
a semiconductor chip comprising back side metal;
a substrate;
an electrically conductive heat spreader directly contacting the back side metal; and
a sintered joint directly contacting the heat spreader and electrically coupling the heat spreader to the substrate.

2. The semiconductor device of claim 1, wherein the heat spreader comprises one of a solid planar Cu layer and a solid planar Ag layer.

3. The semiconductor device of claim 1, wherein the heat spreader has a thickness greater than 4 μm.

4. The semiconductor device of claim 1, wherein the heat spreader comprises carbon nanotubes.

5. The semiconductor device of claim 1, wherein the heat spreader has a thermal conductivity greater than 300 W/mK.

6. The semiconductor device of claim 1, wherein the heat spreader consists of a Cu/Ag layer stack with the Ag layer directly contacting the sintered joint.

7. The semiconductor device of claim 1, wherein the heat spreader consists of a Ni/Cu/Ag layer stack with the Ag layer directly contacting the sintered joint and a thickness of the Cu layer being greater than a thickness of each of the Ni layer and the Ag layer.

8. The semiconductor device of claim 1, wherein the heat spreader consists of a Ni/Cu/Ni/Au layer stack with the Au layer directly contacting the sintered joint and a thickness of the Cu layer being greater than a thickness of each of the Ni layers and the Au layer.

9. The semiconductor device of claim 1, wherein the substrate comprises a metallized ceramic substrate.

10. The semiconductor device of claim 1, wherein the substrate comprises a leadframe.

11. A semiconductor device comprising:
a semiconductor chip comprising back side metal;
a first heat spreader directly contacting the back side metal;
a first substrate;
a first sintered joint directly contacting the first heat spreader and electrically coupling the first heat spreader to the first substrate;
a second heat spreader directly contacting and electrically coupled to a front side of the semiconductor chip;
a second substrate; and
a second sintered joint directly contacting the second heat spreader and electrically coupling the second heat spreader to the second substrate.

12. The semiconductor device of claim 11, wherein the first heat spreader comprises one of Cu and Ag, and
wherein the second heat spreader comprises one of Cu and Ag.

13. The semiconductor device of claim 11, wherein the first heat spreader comprises carbon nanotubes, and
wherein the second heat spreader comprises carbon nanotubes.

14. The semiconductor device of claim 11, wherein the semiconductor chip comprises a power semiconductor chip.

15. The semiconductor device of claim 11, wherein the first substrate comprises a metallized ceramic substrate; and
wherein the second substrate comprises a metallized ceramic substrate.

16. A method for fabricating a semiconductor device, the method comprising:
providing a semiconductor chip comprising back side metal;
forming a first heat spreader directly contacting the back side metal; and
electrically coupling the first heat spreader to a first substrate via a sintering process to provide a first sintered joint directly contacting the first heat spreader and the first substrate.

17. The semiconductor device of claim 16, further comprising:
forming a second heat spreader on a front side of the semiconductor chip; and
electrically coupling the second heat spreader to a second substrate via a sintering process to provide a second sintered joint directly contacting the second heat spreader and the second substrate.

18. The semiconductor device of claim 16, wherein forming the first heat spreader comprises forming a Cu/Ag layer stack.

19. The semiconductor device of claim 16, wherein forming the first heat spreader comprises forming a Ni/Cu/Ag layer stack.

20. The semiconductor device of claim 16, wherein forming the first heat spreader comprises forming a Ni/Cu/Ni/Au layer stack.
